(19) United States
(12) Patent Application Publication
(10) Pub. No.: US 2023/0036704 A1
(43) Pub. Date: Feb. 2, 2023

(54) ARC ION COATING DEVICE AND COATING METHOD

(71) Applicant: JIANGSU XCMG CONSTRUCTION MACHINERY RESEARCH INSTITUTE LTD., JIANGSU (CN)

(72) Inventors: Xuemei ZONG, JIANGSU (CN); Sen FENG, JIANGSU (CN); Sha LI, JIANGSU (CN); Fei GUO, JIANGSU (CN)

(21) Appl. No.: 17/720,482

(22) Filed: Apr. 14, 2022

(30) Foreign Application Priority Data
Jul. 30, 2021 (CN) 202110873377.8

(51) Int. Cl. H05H 1/48; H05H 1/54; C23C 14/32; C23C 14/54

(52) U.S. Cl. CPC H05H 1/48; H05H 1/54; C23C 14/325; C23C 14/54; H05H 2245/40

(57) ABSTRACT

The present disclosure relates to an arc ion coating device and a coating method. The arc ion coating device includes: a vacuum chamber with a vacuum environment inside; an arc generation component disposed in the vacuum chamber and comprising a cathode target, an anode and an arc starter, the cathode target being columnar and configured to release plasmas, and the arc starter being disposed between the cathode target and the anode and configured to generate charged particles to guide a generation of an arc between a side of the cathode target and the anode to coat a workpiece; a support frame disposed in the vacuum chamber, the support frame being disposed at a side of the anode away from the cathode target and configured for a placement of the workpiece; and a power supply component comprising an arc power supply and a first accumulator, the arc power supply having a first output end and a second output end, the first output end being configured to output a pulsed voltage and connected to the arc starter, the second output end being configured to output an adjustable DC voltage and charge the first accumulator, and a negative pole and a positive pole of the first accumulator being connected to the cathode target and the anode, respectively.

### CROSS-REFERENCE TO RELATED APPLICATION

The present application claims priority of Chinese application No. 202110873377.8, filed on Jul. 30, 2021. The disclosed content of the Chinese application is hereby entirely incorporated into the present disclosure.

### TECHNICAL FIELD

The present disclosure relates to a technical field of vacuum coating, and particularly to an arc ion coating device and coating method.

### BACKGROUND

The pulsed arc power supply adopts a pulsed and intermittent large current discharge (≥2000 A), and heat generated by an arc discharge on a surface of a cathode target will be fully taken away by cooling water in a discharge gap, so it can prevent droplets generated by local micro melting of the cathode from affecting the film quality, and it is widely used in coating metal films, alloy films and carbon-based films.

The cathodes of the existing pulsed arc power supply are mostly flat circular targets, which are small in size (≤50 mm) and short in replacement period, and the arc starter is fixedly disposed at one position, so that only a limited area of vacuum arc can be generated on the flat circular target, and the effective range of coating is small and both the thickness and the height of the film prepared within the effective range are uneven. These problems restrict the large-scale and wide-range popularizations and applications of this coating method in the industrial field.

### SUMMARY

According to an aspect of the present disclosure, there is provided an arc ion coating device, including:

a vacuum chamber with a vacuum environment inside;

an arc generation component disposed in the vacuum chamber and including a cathode target, an anode and an arc starter, the cathode target being columnar and configured to release plasmas, and the arc starter being disposed between the cathode target and the anode and configured to generate charged particles to guide a generation of an arc between a side of the cathode target and the anode to coat a workpiece;

a support frame disposed in the vacuum chamber, the support frame being disposed at a side of the anode away from the cathode target and configured for a placement of the workpiece; and

a power supply component including an arc power supply and a first accumulator, the arc power supply having a first output end and a second output end, the first output end being configured to output a pulsed voltage and connected to the arc starter, the second output end being configured to output an adjustable DC voltage and charge the first accumulator, and a negative pole and a positive pole of the first accumulator being connected to the cathode target and the anode, respectively.

In some embodiments, the cathode target has a first center line and is rotatably disposed around the first center line.

In some embodiments, the cathode target has a first center line, and the arc generation component further includes a mounting rod, the arc starter is disposed on the mounting rod and configured to start an arc in a length section of the cathode target to be etched along the first center line.

In some embodiments, the arc starter is movably disposed on the mounting rod to start an arc in various areas of the cathode target along the first center line.

In some embodiments, a moving speed V of the arc starter is determined by the following formula:

V=D×f;

wherein D is a diameter of an effective area etched on a surface of the cathode target by a single arc starter, and f is a frequency of the pulsed voltage output from the first output end.

In some embodiments, a plurality of the arc starters are disposed on the mounting rod at intervals to start an arc in various areas of the cathode target along the first center line.

In some embodiments, a number n of the arc starters is determined by the following formula:

n=H/(D L^{1/2}),

wherein n=1,2,3 . . .

wherein H is an effective length of coating the workpiece along the first center line set according to actual demand, D is a diameter of an effective area etched on a surface of the cathode target by a single arc starter, and L is a distance from the cathode target to a surface of the workpiece.

In some embodiments, the mounting rod is disposed in parallel with the first center line.

In some embodiments, the cathode target has a first center line; in a plane perpendicular to the first center line, the arc starter is disposed at an angle relative to a reference plane formed by the first center line and a central position of the anode, and configured to emit charged particles to an area on the side of the cathode target facing the anode and deviating from the reference plane.

In some embodiments, the arc ion coating device further includes a bias applying component configured to generate bias current to accelerate the plasmas to move toward a surface of the workpiece.

In some embodiments, the bias applying component includes:

a second accumulator with a negative pole and a positive pole connected to the support frame and the grounded vacuum chamber respectively; and

a bias power supply with a third output end configured to output an adjustable DC voltage and charge the second accumulator.

In some embodiments, the bias power supply is electrically connected to the arc power supply, so that the bias power supply synchronously acquires a frequency of the pulsed voltage output from the first output end and a voltage output from the second output end;

wherein the bias applying component is configured to control charging time of the second accumulator according to the frequency of the pulsed voltage output from the first output end and the voltage output from the second output end.

In some embodiments, the arc starter includes an anode part, a cathode part, and a ceramic ring, the ceramic ring is axially connected between the anode part and the cathode part and coated with a conductive material;

wherein the cathode is connected to a negative pole of the first output end, and the anode is connected to a positive pole of the first output end.

In some embodiments, the support frame has a second center line and is rotatably disposed around the second center line; a plurality of sub-supports are disposed at intervals along the second center line of the support frame, and each of the sub-supports is provided with a plurality of workpiece placement positions along a circumferential direction; wherein the cathode target has a first center line, and the second center line is parallel to the first center line.

According to another aspect of the present disclosure, there is provided a coating method based on the arc ion coating device described in the above embodiments, including:

turning on the arc power supply;

powering the arc starter through the pulsed voltage output from the first output end, so that the powered arc starter generates charged particles;

charging the first accumulator through the adjustable DC voltage output from the second output end, so that the first accumulator generates an arc between the side of the cathode target and the anode by discharging, thereby coating the workpiece.

In some embodiments, the arc ion coating device further includes a bias applying component, including: a second accumulator with a negative pole and a positive pole connected to the support frame and the grounded vacuum chamber respectively; and a bias power supply with a third output end configured to output an adjustable DC voltage and charge the second accumulator; the coating method further includes:

turning on the bias power supply to output the adjustable DC voltage to charge the second accumulator;

discharging by the second accumulator to generate bias current, and generating an arc between the cathode target and the anode to coat the workpiece to generate the bias current for accelerating the plasmas to move toward a surface of the workpiece.

In some embodiments, the coating method further includes:

connecting the bias power supply to the arc power supply electrically, so that the bias power supply synchronously acquires a frequency of the pulsed voltage output from the first output end and a voltage output from the second output end;

controlling charging time for the bias power supply to charge the second accumulator, according to the frequency of the pulsed voltage output from the first output end and the voltage output from the second output end.

### BRIEF DESCRIPTION OF THE DRAWINGS

In order to more clearly explain the technical solutions in the embodiments of the present disclosure or in the prior art, the drawings required in the description of the embodiments or the prior art will be briefly introduced below. Obviously, the drawings concerned in the following description just illustrate some embodiments of the present disclosure, and any other drawing can be obtained by those of ordinary skills in the art according to these drawings without paying creative labors.

FIG. 1 illustrates a structural schematic diagram of some embodiments of a coating device of the present disclosure.

FIGS. 2 and 3 illustrate structural schematic diagrams and exploded views of some embodiments of an arc starter in a coating device of the present disclosure.

FIG. 4 illustrates a working principle diagram of a multi-point arc starting mode of the present disclosure.

FIG. 5 illustrates a working principle diagram of a mobile arc starting mode.

Reference numerals

1, vacuum chamber;

2, cathode target; 21, first center line; 22, effective area;

3, arc starter; 3′, mounting rod; 31, cathode part; 32, anode part; 321, first cylindrical section; 322, second cylindrical section; 33, ceramic ring; 331, conductive material;

4, anode;

5, support frame; 51, sub-support; 52, second center line; 53, workpiece placement position;

6, power supply component; 61, arc power supply; 62, first accumulator;

7, bias applying component; 71, bias power supply; 72, second accumulator;

8, plasma;

9, workpiece.

### DETAILED DESCRIPTION

The technical solutions in the embodiments of the present disclosure will be described clearly and completely with reference to the drawings in the embodiments of the present disclosure. Obviously, those described are only a part, rather than all, of the embodiments of the present disclosure. The following description of at least one exemplary embodiment is merely illustrative in fact, and in no way intended to limit the present disclosure, any application thereof or any use thereof. Based on the embodiments of the present disclosure, any other embodiment obtained by those of ordinary skills in the art without paying creative labors should fall within the protection scope of the present disclosure.

Techniques, methods and devices known to those of ordinary skills in related arts may not be discussed in detail, but in appropriate cases, those techniques, methods and devices should be regarded as parts of the specification.

In the description of the present disclosure, it should be understood that any orientation or positional relationship indicated by orientational words such as ‘front, rear, up, down, left, right’, ‘transverse, vertical, perpendicular, horizontal’ and ‘top, bottom’ is usually based on an orientation or positional relationship illustrated in the drawings, and is only for the convenience of describing the present disclosure and simplifying the description. Unless stated to the contrary, these orientational words do not indicate or imply that a referred device or element must have a specific orientation or be constructed and operated in a particular orientation, and they should not be construed as limitations to the protection scope of the present disclosure. The orientational words ‘inner, outer’ mean being inside and outside a contour of each component itself

In the description of the present disclosure, it should be understood that the use of words such as ‘first’ and ‘second’ to define parts and components is only for the convenience of distinguishing the corresponding parts and components. Unless otherwise stated, these words have no special meaning, and they cannot be understood as limitations to the protection scope of the present disclosure.

The present disclosure provides an arc ion coating device and a coating method, which can effectively expand a coating range.

According to the arc ion coating device in the embodiments of the present disclosure, the columnar cathode target has a large size in a length direction, thereby increasing a size of a coating area covered by the cathode target, effectively expanding the coating range, and causing coating thickness of the workpieces to be more uniform. In addition, due to the increase of the size of the cathode target, the target material is resistant to consumption during etching of the cathode target and prolongs a replacement period thereof. Moreover, a pulsed voltage is supplied to the arc starter by the first output end of the arc power supply, and the first accumulator is charged by the second output end of the arc power supply. After charging, the first accumulator supplies power to the cathode target and the anode to produce a pulsed arc, which can produce large instantaneous current to meet the etching requirement of the large-size cathode target.

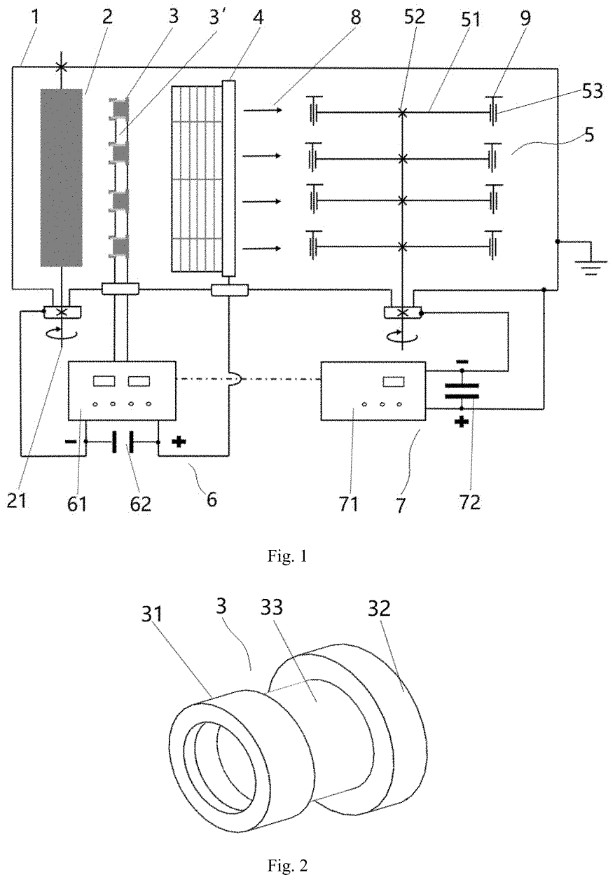

As illustrated in FIGS. 1 to 5, the present disclosure provides an arc ion coating device, which in some embodiments includes a vacuum chamber 1, an arc generation component, a support frame 5 and a power supply component 6.

In which, the vacuum chamber 1 has a vacuum environment inside, so that the arc ion coating is under the vacuum environment. In order for evacuation, the arc ion coating device may further include an evacuating device for evacuating an interior of the vacuum chamber 1.

The arc generation component is disposed in the vacuum chamber 1, and includes a cathode target 2, an anode 4 and an arc starter 3. The cathode target 2 is columnar and configured to release plasmas 8. For example, the cathode target 2 may be made of graphite. The anode 4 is disposed at a position on one side of an outer peripheral surface of the cathode target 2. The anode 4 may be made of a metal material, and designed as a mesh structure for generating a uniform electric field to prolong acceleration time of the plasmas 8. The arc starter 3 is disposed between the cathode target 2 and the anode 4, and is configured to generate charged particles to guide a generation of an arc between a side of the cathode target 2 and the anode 4, thereby releasing the plasmas 8 to etch the cathode target 2, so that the plasma 8 moves from the cathode target 2 to the anode 4 and reaches a workpiece 9 to coat the workpiece 9. For example, the cathode target 2 may be cylindrical or prismatic.

The support frame 5 is disposed in the vacuum chamber 1. The support frame 5 is disposed on a side of the anode 4 away from the cathode target 2 and configured for a placement of the workpiece 9.

The power supply component 6 includes an arc power supply 61 and a first accumulator 62. The arc power supply 61 has a first output end and a second output end. The first output end is configured to output a pulsed voltage and connected to the arc starter 3. The voltage of the first output end is fixed and a frequency of the output pulsed voltage can be adjusted to meet the operating requirement of the arc starter 3. The second output end is configured to output an adjustable DC voltage and charge the first accumulator 62, and a negative pole and a positive pole of the first accumulator 62 are connected to the cathode target 2 and anode 4 respectively. For example, the first accumulator 62 may adopt a capacitor. The electric charges in the first accumulator 62 are the energy source of the large current arc discharge between the cathode target 2 and the anode 4.

In this embodiment, the cathode target 2 is disposed in a columnar form, and compared with the flat circular cathode target, the cathode target 2 has a larger size in a length direction, and its size can be made according to a size of an area where the workpieces 9 to be coated are distributed during the actual production, thereby increasing a size of a coating area covered by the cathode target 2, effectively expanding the coating range, and causing coating thicknesses of the workpieces 9 to be more uniform. In addition, due to the increase of the size of the cathode target 2, the target material is resistant to consumption during etching of the cathode target 2 and prolongs a replacement period thereof, thereby being beneficial to improving the production efficiency of arc ion coating, and suitable for industrial mass productions.

In addition, the pulsed voltage is supplied to the arc starter 3 by the first output end of the arc power supply 61, and the first accumulator 62 is charged by the second output end of the arc power supply 61. After charging, the first accumulator 62 supplies power to the cathode target 2 and the anode 4 to produce a pulsed arc, which can produce large instantaneous current to meet the etching requirement of the large-size cathode target 2 and guarantee the extension of the coating range.

For example, since the generated traditional DC arc is continuous, the consecutive energy input to the cathode target will lead to the generation of ‘droplets’ and cause the pollution of large particles. However, the pulsed arc is adopted in the embodiment of the present disclosure. Because the arc is discontinuous and there is a discharge gap, the heat on the surface of the cathode target 2 will be quickly taken away by the cooling water, so that the generated droplets are less and the pollution of large particles is low. Meanwhile, this instantaneous large current will lead to very high target material ionization rate and ion concentration, and improve the quality of the prepared films.

In some embodiments, as illustrated in FIG. 1, the cathode target 2 has a first center line 21 and is rotatably disposed around the first center line 21. The rotation of the columnar cathode target 2 during the coating can promote uniform etching of a sidewall of the cathode target 2 along a circumferential direction.

In some embodiments, the cathode target 2 has a first center line 21, and the arc generation component further includes a mounting rod 3′, the arc starter 3 is disposed on the mounting rod 3′ and configured to start an arc in a length section of the cathode target 2 to be etched along the first center line 21. For example, the arc starter 3 directly faces a side of the cathode target 2.

In this embodiment, the arc starter 3 is disposed on the mounting rod 3′, so that it is easy to set a position of the arc starter 3 and a positional relationship between the mounting rod 3′ and the first center line 21 according to the coating requirement, thereby ensuring the coating effect.

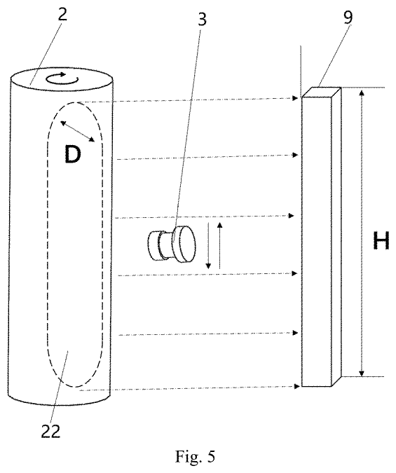

In some embodiments, as illustrated in FIG. 5, the arc starter 3 is movably disposed on the mounting rod 3′ to start an arc in various areas of the cathode target 2 along the first center line 21, and those different arc starting areas are continuous. There may be one arc starter 3, or the cathode target 2 may be divided into a plurality of length areas along the first center line 21, and each of the length areas is movably provided with one arc starter 3.

In this embodiment, the arc starter 3 is movably disposed along the mounting rod 3′, and a small number of arc starters 3 may be provided to start an arc in an entire area of the cathode target 2 which is to be etched along the first center line 21 and consistent with the size of the workpiece 9 to be coated. For example, an arc starting area of a single arc starter 3 on the side of the cathode target 2 is substantially circular. By moving the arc starters 3 in a direction of the first center line 21, the arc starting areas continuously cover the area of the cathode target 2 to be etched, thereby realizing uniform etching and customized design of the surface of the large-size columnar cathode target 2, expanding the effective range of the pulsed arc source coating and improving the uniformity of coating thickness on the surface of the workpiece 9.

For example, as illustrated in FIG. 5, a moving speed V of the arc starter 3 is determined by the following formula:

V=D×f;

wherein D is a diameter of an effective area 22 etched on a surface of the cathode target 2 by a single arc starter 3, and f is a frequency of the pulsed voltage output from the first output end.

In some embodiments, as illustrated in FIGS. 1 and 4, a plurality of arc starters 3 are disposed on the mounting rod 3′ at intervals to start an arc in various areas of the cathode target 2 along the first center line 21. A distance between adjacent arc starters 3 is configured such that adjacent arc starting areas are adjacently disposed to enable the arc starting areas continuously cover the area of the cathode target 2 to be etched.

In this embodiment, a plurality of arc starters 3 are disposed on the mounting rod 3′ at intervals, which increases the etching area of the cathode target 2 which is to be etched along the first center line 21 and consistent with the size of the workpiece 9 to be coated. For example, an arc starting area of a single arc starter 3 on the side of the cathode target 2 is substantially circular. By disposing a plurality of arc starters 3, the arc starting area greatly covers the area of the cathode target 2 to be etched, thereby realizing uniform etching and customized design of the surface of the large-size columnar cathode target 2, expanding the effective range of the pulsed arc source coating and improving the uniformity of coating thickness on the surface of the workpiece 9.

For example, a number n of the arc starters 3 is determined by the following formula:

n=H/(D L^{1/2}),

wherein n=1,2,3 . . .

wherein H is an effective length of coating the workpiece 9 along the first center line 21 set according to actual demand, D is a diameter of an effective area 22 etched on a surface of the cathode target 2 by a single arc starter 3, and L is a distance from the cathode target 2 to a surface of the workpiece 9.

In some embodiments, the mounting bar 3′ is disposed in parallel with the first centerline 21. This structure can ensure that a distance between the arc starter 3 and the sidewall of the cathode target 2 is consistent during coating, thereby improving the uniformity of the surface etching of the cathode target 2. For example, both the first center line 21 and the mounting rod 3′ may be vertically disposed.

For example, in the embodiment where the arc starter 3 is movably disposed, a moving trajectory of the arc starter 3 is straight, and the distance from the sidewall of the cathode target 2 is the consistent whenever the arc starter 3 moves to any position. Alternatively, the arc starter 3 can also move along other types of paths. In the embodiment where a plurality of arc starters 3 are disposed, the plurality of arc starters 3 are disposed along a straight trajectory, and each of the arc starters 3 has an equal distance to the sidewall of the cathode target 2. Alternatively, the plurality of arc starters 3 may also be arranged in other forms.

In some embodiments, as illustrated in FIGS. 4 and 5, the cathode target 2 has a first center line 21. In a plane perpendicular to the first center line 21, the arc starter 3 is disposed at an angle with respect to a reference plane formed by the first center line 21 and a center position of the anode 4, and is configured to emit charged particles to an area on the side of the cathode target 2 facing the anode 4 and deviating from the reference plane.

In this embodiment, by disposing the arc starter 3 at an angle to start an arc in a side area of the columnar cathode target 2, the movement of the plasmas 8 generated in the arc starting and etching area toward the anode 4 will not be affected. Even if a plurality of arc starters 3 are disposed on the mounting rod 3′, the plurality of arc starters 3 are distributed linearly, without affecting the movement of the plasmas 8 generated in the arc starting and etching area toward the anode 4, and the coating effect can be improved. However, in the prior art, if a disc-shaped cathode target is provided with a plurality of arc starters on one side, the movement of the plasmas generated in the arc starting area toward the anode will be blocked by the plurality of arc starters, so that it is impossible to dispose a plurality of arc starters, and a vacuum arc can only be generated in a limited area.

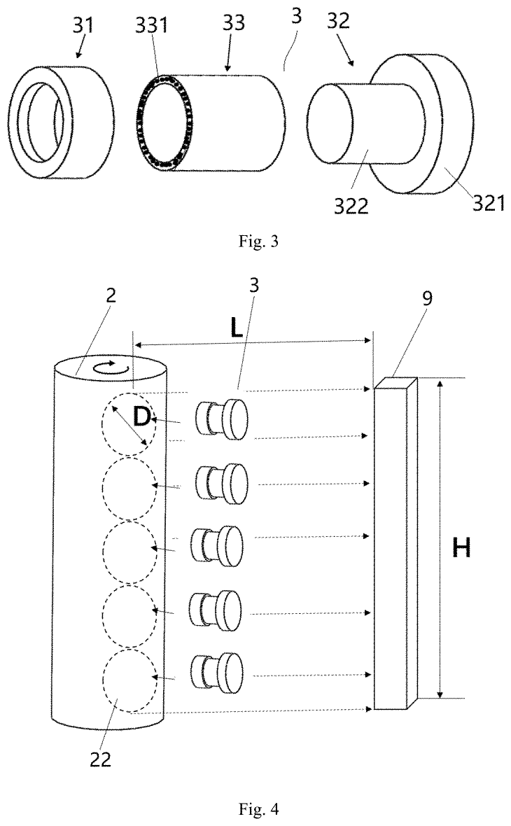

In some embodiments, as illustrated in FIGS. 2 and 3, the arc starter 3 includes an anode part 32, a cathode part 31, and the ceramic ring 33 is axially connected between the anode part 32 and the cathode part 31 and coated with a conductive material 331. The cathode part 31 is connected to the negative pole of the first output end, and the anode part 32 is connected to the positive pole of the first output end.

A voltage applied between the anode part 32 and the cathode part 31 will cause a small current discharge, which generates charged particles. The charged particles will reduce a breakdown voltage between the cathode target 2 and the anode 4, cause an arc discharge between the cathode target 2 and the anode 4, and etch the surface of the cathode target 2 to generate coating cations. This arc starter 3 has a simple structure and a high stability.

For example, both the anode part 32 and the cathode part 31 may be made of graphite. The cathode part 31 has an annular structure. The anode part 32 includes a first cylindrical section 321 and a second cylindrical section 322 which are axially connected to each other, and a diameter of the second cylindrical section 322 is smaller than that of the first cylindrical section 321. The ceramic ring 33 is disposed to sleeve on the second cylindrical section 322, the cathode part 31 is disposed to sleeve outside the ceramic ring 33, and the first cylindrical section 321 and the cathode part 31 are axially spaced apart from each other. The mounting rod 3′ may pass through a center hole of the arc starter 3.

In some embodiments, as illustrated in FIG. 1, the arc ion coating device further includes a bias applying component 7 configured to generate bias current, which is also a pulsed current, to accelerate the plasmas 8 to move toward the surface of the workpiece 9.

In this embodiment, the bias current can be effectively applied to the plasmas 8 and a positive electric field can be formed on the plasmas 8, so as to further increase the density and energy of the plasmas 8 generated by a pulsed arc ion source, thereby enhancing a bonding force between the coated film and the workpiece 9, expanding the application range of the pulsed arc ion source in the industrial field, and realizing industrial, large-scale and high-efficiency productions.

In some embodiments, the bias applying component 7 includes a second accumulator 72 and a bias power supply 71. A negative pole and a positive pole of the second accumulator 72 are respectively connected to the support frame 5 and the grounded vacuum chamber 1, and the second accumulator 72 for example may be a capacitor. The bias power supply 71 has a third output end configured to output an adjustable DC voltage and charge the second accumulator 72. The electric charges in the second accumulator 72 are the source of a large current required when the pulsed arc is biased.

The pulsed arc power supply has very high ionization rate, ion concentration and ionization current (≥150 A) during operation. In the prior art, since the supplied current usually has a limit value less than 100 A and cannot keep pace with the plasmas generated in the pulsed discharge, it is difficult to generate an electric field of bias current between the cathode target 2 and the anode 4 through the power supply, while the electric field for example may filter large particles and reduce the deposition thereof on the workpiece.

In the present disclosure, the second accumulator 72 is be charged by the bias power supply 71, and the charged second accumulator 72 provides a voltage for the generation of the bias current, so that a very large instantaneous current can be generated to form a positive electric field between the vacuum chamber 1 and the support frame 5, and accelerate cations generated in the pulsed arc discharge, thereby improving the bonding force between the coated film and the workpiece 9 and optimizing the coating effect.

In some embodiments, the bias power supply 71 is electrically connected to the arc power supply 61, so that the bias power supply 71 synchronously acquires a frequency of the pulsed voltage output from the first output end and a voltage output from the second output end, wherein the bias applying component 7 is configured to control charging time of the second accumulator 72 according to the frequency of the pulsed voltage output from the first output end and the voltage output from the second output end. For example, the bias power supply 71 and the second accumulator 72 may be provided with switches to switch between On and Off states according to the charging time.

In this embodiment of the present disclosure, the charging time of the second accumulator 72 can be determined according to the actual energy demand of vacuum coating, so as to apply the required bias current. The bias power supply 71 operates in a slave mode, and is electrically connected to the arc power supply 61 so as to synchronously output operating parameters of the arc power supply 61; the large current required by the pulsed arc power supply is generated by the second accumulator 72, thereby effectively applying the operating bias, further enhancing the energy of the plasmas 8, improving the bonding force of the coated film, and expanding the application range of the pulsed arc power supply.

In some embodiments, as illustrated in FIG. 1, the support frame 5 has a second center line 52 and is rotatably disposed around the second center line 52; a plurality of sub-supports 51 are disposed at intervals along the second center line 52 of the support frame 5, and each of the sub-supports 51 is provided with a plurality of workpiece placement positions 53 along a circumferential direction; wherein the cathode target 2 has a first center line 21, and the second center line 52 is parallel to the first center line 21.

In this embodiment, since the large-size cathode target 2 is disposed along the first center line 21 so that the plasmas 8 is released in a large area, a multi-layer sub-support 51 may be rotatably disposed around the second center line 52, and each of the workpiece placement positions 53 may rotate, along an axis thereof, the workpiece 9, thereby expanding the effective range of the pulsed arc source coating while uniformly coating the surfaces of the plurality of workpieces 9, which is suitable for mass productions.

In some specific embodiments, as illustrated in FIG. 1, by simultaneously starting an arc by a plurality of arc starters 3 or moving the arc starter 3 along the mounting rod 3′, the effective etching area on the side of the cathode target 2 for the vacuum arc is increased, so that the plasmas 8 is uniformly generated on a surface of a target material with a larger size, thereby expanding the effective range of the coating and improving the uniformity of the film thickness within the effective range. The charging and discharging of the second accumulator 72 by the bias power supply 71 generate a pulsed current output synchronously with the discharging of the pulse arc power supply 61, which can effectively apply a bias to the pulsed arc power supply, further enhance energy of ions and improve the bonding force between the film and the matrix.

The specific process implementation procedure of the coating device is as follows:

After the vacuum chamber 1 is evacuated, the cathode target 2 is rotated around the first center line 21; the second output end of the arc power supply 61 charges the first accumulator 62 and provides a synchronous signal to the bias power supply 71; the bias power supply 71 calculates charging time according to the signal and charges the second accumulator 72 within the calculated charging time. The first output end of the arc power supply 61 provides a pulsed voltage to the arc starter 3, and the arc starter 3 causes a small current discharge to generate electric charges, thereby reducing a breakdown voltage between the cathode target 2 and the anode 4. At this time, the first accumulator 62 discharges, thereby causing a large current arc discharge on the surface of the cathode target 2, etching the surface of the cathode target 2 and generating the plasmas 8. At the same time, the second accumulator 72 discharges, thereby generating bias current synchronized with the arc discharge, which accelerates the plasmas 8 to move toward the surface of the workpiece 9, further increases the energy of ions in the plasmas 8, and improves the bonding force between the film and the workpiece 9.

In a multipoint arc starting mode, the plurality of arc starters 3 will trigger corresponding number of vacuum arc areas to uniformly etch the surface of cathode target 2, the number of the arc starters 3 is n. In a movable arc starting mode, the arc starter 3 will only trigger one vacuum arc area, and the vacuum arc moves on the surface of the cathode target 2 along with the movement of the arc starter 3, thereby realizing uniform etching on the surface of the cathode target 2.

Further, the present disclosure provides a coating method based on the arc ion coating device described in the above embodiments, which in some embodiments includes:

step 101: turning on the arc power supply 61;

step 102: powering the arc starter 3 through the pulsed voltage output from the first output end, so that the powered arc starter 3 generates charged particles;

step 103: charging the first accumulator 62 through the adjustable DC voltage output from the second output end, so that the first accumulator 62 generates an arc between the side of the cathode target 2 and the anode 4 by discharging, thereby coating the workpiece 9.

In the coating method of this embodiment, the pulsed voltage is supplied to the arc starter 3 by the first output end of the arc power supply 61, and the first accumulator 62 is charged by the second output end of the arc power supply 61. After charging, the first accumulator 62 supplies power to the cathode target 2 and the anode 4 to generate a pulsed arc, which can produce large instantaneous current to meet the etching requirement of the large-size columnar cathode target 2 and guarantee the extension of the coating range.

In some embodiments, the arc ion coating device further includes a bias applying component 7, including: a second accumulator 72 with a negative pole and a positive pole connected to the support frame 5 and the grounded vacuum chamber 1 respectively; and a bias power supply 71 with a third output end configured to output an adjustable DC voltage and charge the second accumulator 72; the coating method further includes:

step 104: turning on the bias power supply 71 to output the adjustable DC voltage to charge the second accumulator 72;

step 105: discharging by the second accumulator 72 to generate bias current, and generating an arc between the cathode target 2 and the anode 4 to coat the workpiece 9 to generate the bias current for accelerating the plasmas 8 to move toward a surface of the workpiece 9.

Step 104 may be performed synchronously with step 101 or after step 101. In this embodiment, the second accumulator 72 is charged by the bias power supply 71, and the charged second accumulator 72 provides a voltage to generate the bias current, so that large instantaneous current is generated to form a positive electric field between the vacuum chamber 1 and the support frame 5, and accelerate cations generated in the pulsed arc discharge, thereby improving the bonding force between the coated film and the workpiece 9 and optimizing the coating effect.

In some embodiments, the coating method further includes:

step 106: connecting the bias power supply 71 to the arc power supply 61 electrically, so that the bias power supply 71 synchronously acquires a frequency of the pulsed voltage output from the first output end and a voltage output from the second output end;

step 107: controlling charging time for the bias power supply 71 to charge the second accumulator 72, according to the frequency of the pulsed voltage output from the first output end and the voltage output from the second output end.

The precedence relationship between step 106 and steps 101 and 104 is not limited, and step 107 can be performed during the coating. In this embodiment, the charging time of the second accumulator 72 can be determined according to the actual energy demand of vacuum coating, so as to apply the required bias current. The bias power supply 71 operates in a slave mode, and is electrically connected to the arc power supply 61 so as to synchronously output operating parameters of the arc power supply 61; the large current required by the pulsed arc power supply is generated by the second accumulator 72, thereby effectively applying the operating bias, further enhancing the energy of the plasmas 8, improving the bonding force of the coated film, and expanding the application range of the pulsed arc power supply.

Those described above are just exemplary embodiments of the present disclosure, rather than limitations thereto. Any modification, equivalent substitution, improvement, etc. made within the spirit and principle of the present disclosure should fall within the protection scope of the present disclosure.

What is claimed is:

1. An arc ion coating device, comprising:
a vacuum chamber with a vacuum environment inside;
an arc generation component, disposed in the vacuum chamber and comprising a cathode target, an anode and an arc starter, the cathode target being columnar and configured to release plasmas, and the arc starter being disposed between the cathode target and the anode and configured to generate charged particles to guide a generation of an arc between a side of the cathode target and the anode to coat a workpiece;
a support frame, disposed in the vacuum chamber, the support frame being arranged at a side of the anode away from the cathode target and configured for a placement of the workpiece; and
a power supply component, comprising an arc power supply and a first accumulator, the arc power supply having a first output end and a second output end, the first output end being configured to output a pulsed voltage and connected to the arc starter, the second output end being configured to output an adjustable DC voltage and charge the first accumulator, and a negative pole and a positive pole of the first accumulator being connected to the cathode target and the anode, respectively.

2. The arc ion coating device according to claim 1, wherein the cathode target has a first center line and is rotatably disposed around the first center line.

3. The arc ion coating device according to claim 1, wherein the cathode target has a first center line, and the arc generation component further comprises a mounting rod, the arc starter is disposed on the mounting rod and configured to start an arc in a length section of the cathode target to be etched along the first center line.

4. The arc ion coating device according to claim 3, wherein the arc starter is movably disposed on the mounting rod to start an arc in various areas of the cathode target along the first center line.

5. The arc ion coating device according to claim 4, wherein a moving speed V of the arc starter is determined by the following formula:
V=D×f;
wherein D is a diameter of an effective area etched on a surface of the cathode target by a single arc starter, and f is a frequency of the pulsed voltage output from the first output end.

6. The arc ion coating device according to claim 3, wherein a plurality of the arc starters are disposed on the mounting rod at intervals to start an arc in various areas of the cathode target along the first center line.

7. The arc ion coating device according to claim 6, wherein a number n of the arc starters is determined by the following formula:
n=H/(D L^{1/2}),
wherein n=1,2,3 . . .
wherein H is an effective length of coating the workpiece along the first center line set according to actual demand, D is a diameter of an effective area etched on a surface of the cathode target by a single arc starter, and L is a distance from the cathode target to a surface of the workpiece.

8. The arc ion coating device according to claim 4, wherein the mounting rod is disposed in parallel with the first center line.

9. The arc ion coating device according to claim 1, wherein the cathode target has a first center line; in a plane perpendicular to the first center line, the arc starter is disposed at an angle relative to a reference plane formed by the first center line and a central position of the anode, and configured to emit charged particles to an area on the side of the cathode target facing the anode and deviating from the reference plane.

10. The arc ion coating device according to claim 1, further comprising a bias applying component configured to generate bias current to accelerate the plasmas to move toward a surface of the workpiece.

11. The arc ion coating device according to claim 10, wherein the bias applying component comprises:
a second accumulator with a negative pole and a positive pole connected to the support frame and the grounded vacuum chamber respectively; and
a bias power supply with a third output end configured to output an adjustable DC voltage and charge the second accumulator.

12. The arc ion coating device according to claim 11, wherein the bias power supply is electrically connected to the arc power supply, so that the bias power supply is able to synchronously acquire a frequency of the pulsed voltage output from the first output end and a voltage output from the second output end; and
wherein the bias applying component is configured to control charging time of the second accumulator according to the frequency of the pulsed voltage output from the first output end and the voltage output from the second output end.

13. The arc ion coating device according to claim 1, wherein the arc starter comprises an anode part, a cathode part, and a ceramic ring, the ceramic ring is axially connected between the anode part and the cathode part and coated with a conductive material; and
wherein the cathode is connected to a negative pole of the first output end, and the anode is connected to a positive pole of the first output end.

14. The arc ion coating device according to claim 1, wherein the support frame has a second center line and is rotatably disposed around the second center line; a plurality of sub-supports are disposed at intervals along the second center line of the support frame, and each of the sub-supports is provided with a plurality of workpiece placement positions along a circumferential direction; wherein the cathode target has a first center line, and the second center line is parallel to the first center line.

15. A coating method based on the arc ion coating device according to claim 1, comprising:
turning on the arc power supply;
powering the arc starter through the pulsed voltage output from the first output end, so that the powered arc starter generates charged particles; and
charging the first accumulator through the adjustable DC voltage output from the second output end, so that the first accumulator generates an arc between the side of the cathode target and the anode by discharging, thereby coating the workpiece.

16. The coating method according to claim 15, wherein the arc ion coating device further comprises a bias applying component, comprising: a second accumulator with a negative pole and a positive pole connected to the support frame and the grounded vacuum chamber respectively; and a bias power supply with a third output end configured to output an adjustable DC voltage and charge the second accumulator; the coating method further comprises:
turning on the bias power supply to output the adjustable DC voltage to charge the second accumulator; and
discharging by the second accumulator to generate bias current, and generating an arc between the cathode target and the anode to coat the workpiece to generate the bias current for accelerating the plasmas to move toward a surface of the workpiece.

17. The coating method according to claim 16, further comprising:
connecting the bias power supply to the arc power supply electrically, so that the bias power supply synchronously acquires a frequency of the pulsed voltage output from the first output end and a voltage output from the second output end; and
controlling charging time for the bias power supply to charge the second accumulator, according to the frequency of the pulsed voltage output from the first output end and the voltage output from the second output end.
